(19) United States
(12) Patent Application Publication
(10) Pub. No.: US 2008/0309649 A1
(43) Pub. Date: Dec. 18, 2008

(54) CURRENT DRIVE CIRCUIT AND DISPLAY APPARATUS

(76) Inventors: Hiroshi Kojima, Kyoto (JP); Makoto Mizuki, Kyoto (JP); Munehiko Ogawa, Osaka (JP); Kazuyoshi Nishi, Kyoto (JP); Tetsuro Oomori, Osaka (JP)

Correspondence Address: MCDERMOTT WILL & EMERY LLP, 600 13TH STREET, NW, WASHINGTON, DC, 20005-3096, US

(21) Appl. No.: 12/135,627

(22) Filed: Jun. 9, 2008

(30) Foreign Application Priority Data
Jun. 15, 2007 (JP) 2007-158270

(51) Int. Cl. G06F 3/038; H03B 1/00

(52) U.S. Cl. 345/204; 327/108

(57) ABSTRACT

A current drive circuit supplies a driving current to a pixel portion included in a current-driven display panel. A driving current generator includes an output terminal for supplying the driving current. A protective transistor has a drain connected to the pixel portion, a source connected to the output terminal, and a gate to which a first bias voltage is supplied. The first bias voltage has a voltage level lower than or equal to a voltage level obtained by adding the threshold voltage of the protective transistor to the breakdown voltage of the driving current generator.

### BACKGROUND OF THE INVENTION

The present invention relates to current drive circuits for driving current-driven devices such as organic electro luminescence (EL) devices, and to display apparatus provided with such current drive circuits.

In recent years, display apparatus using current-driven light-emitting devices (e.g., organic EL devices or inorganic EL devices) have been actively developed. Such display apparatus includes: a display panel including a plurality of pixel portions each provided with a light-emitting device; and a current drive circuit for supplying a driving current corresponding to display data. In this display apparatus, each of the pixel portions copies a driving current supplied by the current drive circuit in itself so that the light-emitting device provided in this pixel portion emits light according to the driving current copied therein, thereby displaying an image on the display panel.

As disclosed in WO 03/091977, a current drive circuit generally includes: a plurality of drive transistors for generating a unit current: an output terminal connected to a display panel; and a plurality of switches connected between the drains of the drive transistors and the output terminal. The ON/OFF states of the switches are controlled according to display data so that a driving current corresponding to the display data is supplied from the output terminal to the display panel.

While a driving current is copied in a pixel portion of the display panel, a voltage generated at the pixel portion is applied to the output terminal of the current drive circuit. Therefore, to prevent breakdown, the breakdown voltage of the current drive circuit (e.g., the breakdown voltage of the drive transistors) needs to be higher than the voltage generated at the display panel. In view of this, a conventional current drive circuit includes transistors having a breakdown voltage substantially equal to a breakdown voltage of a display panel.

However, in such a conventional current drive circuit, as the voltage generated at the display panel increases, the required breakdown voltage of the current drive circuit increases. In general, the higher the breakdown voltage of a transistor is, the wider the variation range in characteristics of the transistor is. To suppress this characteristic variation, the transistor size needs to be increased, thus making it difficult to reduce the circuit scale of the current drive circuit. Moreover, additional process steps for increasing the breakdown voltage are required in the process of fabricating transistors, resulting in increase of the fabrication cost.

A higher voltage applied to the output terminal of the current drive circuit is more likely to cause deterioration of the current drive circuit. Therefore, it is difficult to accurately supply a driving current for a long period.

### SUMMARY OF THE INVENTION

In an aspect of the present invention, a current drive circuit for supplying a driving current to a pixel portion included in a current-driven display panel includes: a driving current generator including an output terminal for supplying the driving current; and a protective transistor having a drain connected to the pixel portion, a source connected to the output terminal, and a gate to which a first bias voltage is supplied. The first bias voltage has a voltage level lower than or equal to a voltage level obtained by adding a threshold voltage of the protective transistor to a breakdown voltage of the driving current generator.

In this current drive circuit, the voltage level at the output terminal of the driving current generator is limited by the protective transistor, thereby preventing breakdown of the current drive circuit. In addition, the breakdown voltage of the driving current generator is lower than that in conventional circuits. Thus, the circuit scale and fabrication cost of the current drive circuit are reduced. Moreover, the life of the current drive circuit is longer than that of conventional circuits, thus accurately supplying a driving current for a long period.

Preferably, the current drive circuit further includes a control transistor interposed between the pixel portion and the protective transistor. The control transistor has a drain connected to the pixel portion, a source connected to the drain of the protective transistor, and a gate to which a control signal for controlling ON/OFF of the control transistor is supplied.

In this current drive circuit, the control transistor allows the connection state between the display panel and the driving current generator to be switched, thus protecting the driving current generator against a voltage variation caused by voltage control on the display panel.

Preferably, the current drive circuit further includes a compensation transistor having a drain, a source and a gate. The drain and the source of the compensation transistor are connected to the source of the control transistor. The gate of the compensation transistor receives a compensation signal. The compensation signal is a signal for controlling ON/OFF of the compensation transistor. A voltage level of the compensation signal varies inversely with a variation of the control signal.

In this current drive circuit, the compensation transistor suppresses a variation in the source voltage of the control transistor, resulting in stabilizing the drain voltage of the protective transistor.

Preferably, the current drive circuit further includes a clamping transistor interposed between the pixel portion and the protective transistor. The clamping transistor has a drain connected to the pixel portion, a source connected to the drain of the protective transistor, and a gate to which a second bias voltage having a voltage level lower than or equal to a voltage level obtained by adding a threshold voltage of the clamping transistor to a breakdown voltage of the protective transistor is supplied.

In this current drive circuit, the clamping transistor stabilizes the drain voltage of the protective transistor, thereby suppressing a variation of a driving current caused by a channel-length modulation effect of the protective transistor.

In another aspect of the present invention, a current drive circuit for supplying a driving current to a pixel portion included in a current-driven display panel includes: a plurality of drive transistors; and a plurality of switching transistors each connected between an associated one of the drive transistors and an output terminal for supplying the driving current. Each of the switching transistors has a drain connected to the output terminal, a source connected to a drain of an associated one of the drive transistors, and a gate to which a selection signal for controlling ON/OFF of the switching transistor is supplied. A voltage level of the selection signal varies in a range between a non-conducting level at which the switching transistor is OFF and a conducting level lower than or equal to a voltage level obtained by adding a threshold voltage of the switching transistor to a breakdown level of the drive transistor.

In this current drive circuit, the drain voltage of the drive transistor is limited by the switching transistor, thereby preventing breakdown of the drive transistor. In addition, the breakdown voltage of the drive transistor is lower than that in conventional circuits. Accordingly, the circuit scale and fabrication cost of the current drive circuit are reduced. Moreover, the life of the drive transistor is longer than that in conventional circuits, thus accurately supplying a driving current for a long period.

In still another aspect of the present invention, a current-driven display panel driven by a driving current supplied from an output terminal of a current drive circuit includes: a pixel portion to which the driving current is supplied; and a protective transistor having a drain connected to the pixel portion, a source connected to the output terminal, and a gate to which a bias voltage is supplied. The bias voltage has a voltage level lower than or equal to a voltage level obtained by adding a threshold voltage of the protective transistor to a breakdown voltage of the current drive circuit.

In this display panel, the voltage level of the output terminal of the driving current generator is limited by the protective transistor, thereby preventing breakdown of the current drive circuit. In addition, the breakdown voltage of the current drive circuit is lower than that in conventional circuits. Accordingly, the circuit scale and fabrication cost of the current drive circuit are reduced. Moreover, the life of the current drive circuit is longer than that of conventional circuits, thus accurately supplying a driving current for a long period.

### BRIEF DESCRIPTION OF THE DRAWINGS

FIG. 1 is a view illustrating a configuration of display apparatus according to a first embodiment of the present invention.

FIG. 2 is a view illustrating a configuration of a first modified example of the current drive circuit shown in FIG. 1.

FIG. 3 is a view illustrating a configuration of display apparatus according to a second embodiment of the present invention.

FIG. 4 is a view illustrating a configuration of a first modified example of the current drive circuit shown in FIG. 3.

FIG. 5 is a view illustrating a configuration of a second modified example of the current drive circuit shown in FIG. 3.

FIG. 6 is a view illustrating a configuration of display apparatus according to a third embodiment of the present invention.

FIG. 7 is a view illustrating a configuration of a first modified example of the current drive circuit shown in FIG. 6.

FIG. 8 is a view illustrating a configuration of a second modified example of the current drive circuit shown in FIG. 6.

FIG. 9 is a view illustrating a configuration of display apparatus according to a fourth embodiment of the present invention.

FIG. 10 is a view illustrating a configuration of a modified example of the display apparatus shown in FIG. 1.

### DETAILED DESCRIPTION OF THE INVENTION

Hereinafter, embodiments of the present invention will be described in detail with reference to the accompanying drawings. In the drawings, the same or equivalent components are denoted by the same reference numerals and description thereof is not repeated.

### Embodiment 1

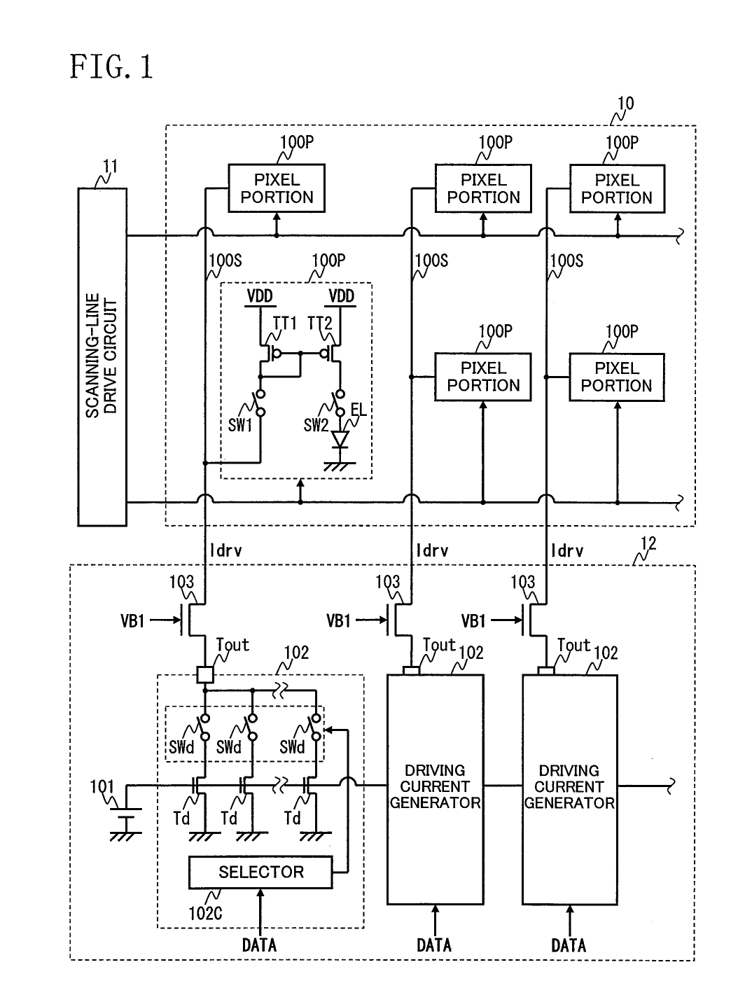

FIG. 1 illustrates a configuration of display apparatus according to a first embodiment of the present invention. The display apparatus includes: a display panel 10; a scanning-line drive circuit 11; and a current drive circuit 12.

### [Display Panel]

The display panel 10 includes: a plurality of pixel portions 100P, 100P, . . . arranged in a matrix; and a plurality of source lines 100S, 100S, . . . extending in parallel with one another. The pixel portions 100P, 100P, . . . are respectively associated with the source lines 100S, 100S, . . . and each includes a current-driven light-emitting device (which is herein an organic EL device). Each of the pixel portions 100P, 100P, . . . has two modes: a current copy mode in which a driving current Idrv supplied to the associated source line is copied; and a current drive mode in which the organic EL device included therein is driven according to the driving current Idrv copied therein.

Each pixel portion 100P includes: transistors TT1 and TT2 whose sources receive a power supply voltage VDD (i.e., a power supply voltage of the display panel); and switches SW1 and SW2, for example, in addition to the organic EL device EL. In the current copy mode, the switch SW1 turns ON, whereas the switch SW2 turns OFF. Then, a gate voltage corresponding to a driving current Idrv supplied to the source line is generated at the gate of the transistor TT1. In the current drive mode, the switch SW1 turns OFF, whereas the switch SW2 turns ON. Then, a current (i.e., a driving current Idrv) corresponding to the gate voltage of the transistor TT2 is supplied to the organic EL device EL.

### [Scanning-Line Drive Circuit]

The scanning-line drive circuit 11 drives the pixel portions 100P, 100P, . . . included in the display panel 10 for every horizontal line. More specifically, the scanning-line drive circuit 11 selects a group of the pixel portions 100P, 100P, . . . belonging to one horizontal line, and sets the selected pixel portions 100P, 100P, . . . at the current copy mode. When copying of a driving current is completed, the scanning-line drive circuit 11 sets these pixel portions 100P, 100P, . . . at the current drive mode.

### [Current Drive Circuit]

The current drive circuit 12 supplies driving currents Idrv, Idrv, . . . corresponding to display data DATA, DATA, . . . indicating luminance levels of pixels to the respective source lines 100S, 100S, . . . . The current drive circuit 12 includes: a voltage source 101 for supplying a bias voltage; driving current generators 102, 102, . . . respectively associated with the source lines 100S, 100S, . . . ; and protective transistors 103, 103, . . . respectively associated with the driving current generators 102, 102, . . . .

Each driving current generator 102 includes: drive transistors Td, Td, . . . ; switches SWd, SWd, . . . ; an output terminal Tout; and a selector 102C, for example. The gates of the drive transistors Td, Td, . . . receive a bias voltage from the voltage source 101. The switches SWd, SWd, . . . are connected between the drains of the respective drive transistors Td, Td . . . and the output terminal Tout. The selector 102C controls ON/OFF of the switches SWd, SWd, . . . according to display data DATA. In this manner, a driving current Idrv corresponding to the display data DATA is supplied through the output terminal Tout.

Each protective transistor 103 has: a drain connected to an associated source line 100S; a source connected to the output terminal Tout of an associated driving current generator 102; and a gate to which a bias voltage VB1 is supplied. The voltage level of the bias voltage VB1 corresponds to a voltage level at which the protective transistor 103 comes to be in a saturation region, and is lower than or equal to a voltage level obtained by adding the threshold voltage of the protective transistor 103 to the breakdown voltage of the driving current generator 102 (e.g., the breakdown voltage of the drive transistor Td). The bias voltage VB1 is supplied concurrently with, or before, the start-up of the driving current generator 102.

While a driving current Idrv is copied in a pixel portion 100P, the drain voltage of the transistor TT1 of the pixel portion 100P is equal to the gate voltage thereof. That is, the gate voltage generated at the pixel portion 100P is applied to the source line 100S associated with this pixel portion 100P. On the other hand, since a bias voltage VB1 is supplied to the gate of the protective transistor 103, the voltage level of the output terminal Tout associated with this protective transistor 103 becomes equal to or lower than the voltage level obtained by subtracting the threshold voltage of the protective transistor 103 from the voltage level of the bias voltage VB1. That is, the voltage level of the output terminal Tout is controlled not to exceed the breakdown voltage of the driving current generator 102.

Since the protective transistor 103 operates in the saturation region, no current variation occurs between the source and drain of the protective transistor 103. Accordingly, a driving current Idrv generated by the driving current generator 102 is accurately supplied to the source line 100S.

As described above, the voltage level at the output terminal Tout of the driving current generator 102 is limited by the protective transistor 103, thereby preventing breakdown of the current drive circuit 12 (more specifically, the driving current generator 102). In addition, the breakdown voltage of the current drive circuit 12 is allowed to be set independently of the power supply voltage of the display panel 10 so that the breakdown voltage of the current drive circuit 12 is lower than that in conventional circuits. This suppresses a variation in characteristics of the transistors Td and other elements, thus reducing the circuit scale and fabrication cost of the current drive circuit 12.

Further, the voltage level of a voltage applied to the output terminal Tout of the driving current generator 102 in writing a driving current Idrv is allowed to be set lower than that in conventional circuits. Thus, the life of the current drive circuit 12 is longer than that in conventional circuits. In this manner, characteristic deterioration caused by using the current drive circuit 12 is suppressed, thus accurately supplying a driving current Idrv for a longer period than in conventional circuits.

On a line between the source of the protective transistor 103 and the output terminal Tout, noise might be induced by a voltage variation on an adjacent line. In view of this, the protective transistor 103 is preferably located near the output terminal Tout. The smaller the distance between the source of the protective transistor 103 and the output terminal Tout is, the greater the effect of suppressing a voltage variation at the output terminal Tout caused by such noise is.

### Modified Example 1 of Embodiment 1

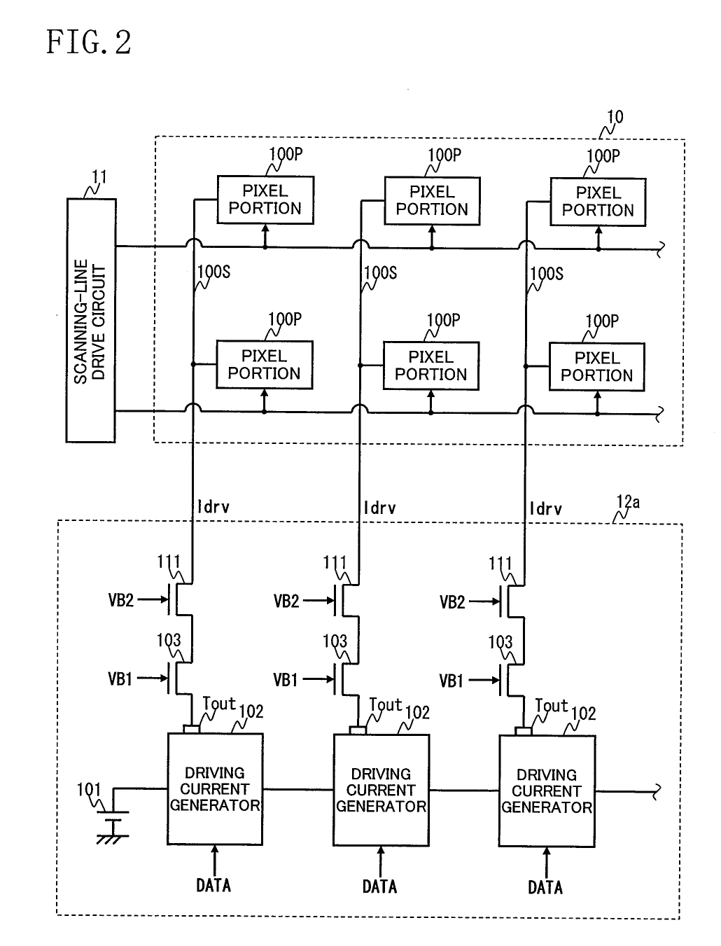

As illustrated in FIG. 2, clamping transistors 111, 111, . . . may be interposed between the drains of the protective transistors 103, 103 . . . and the source lines 100S, 100S, . . . . In a current drive circuit 12a shown in FIG. 2, each clamping transistor 111 has: a drain connected to an associated source line 100S; a source connected to the drain of an associated protective transistor 103; and a gate to which a bias voltage VB2 is supplied. The voltage level of the bias voltage VB2 corresponds to a voltage level at which the clamping transistor 111 comes to be in a saturation region, and is lower than or equal to a voltage level obtained by adding the threshold voltage of the clamping transistor 111 to the breakdown voltage of the protective transistor 103. The bias voltage VB2 is supplied concurrently with, or before, the start-up of the driving current generator 102.

In this manner, the clamping transistor 111 stabilizes the drain voltage of the protective transistor 103 so that a variation of a driving current Idrv caused by a channel-length modulation effect of the protective transistor 103 is suppressed. Accordingly, breakdown is more effectively suppressed.

The clamping transistor 111 is preferably located near the drain of the protective transistor 103. The smaller the distance between the source of the clamping transistor 111 and the drain of the protective transistor 103 is, the greater the effect of suppressing a drain voltage variation of the protective transistor 103 caused by noise on another line is.

### Embodiment 2

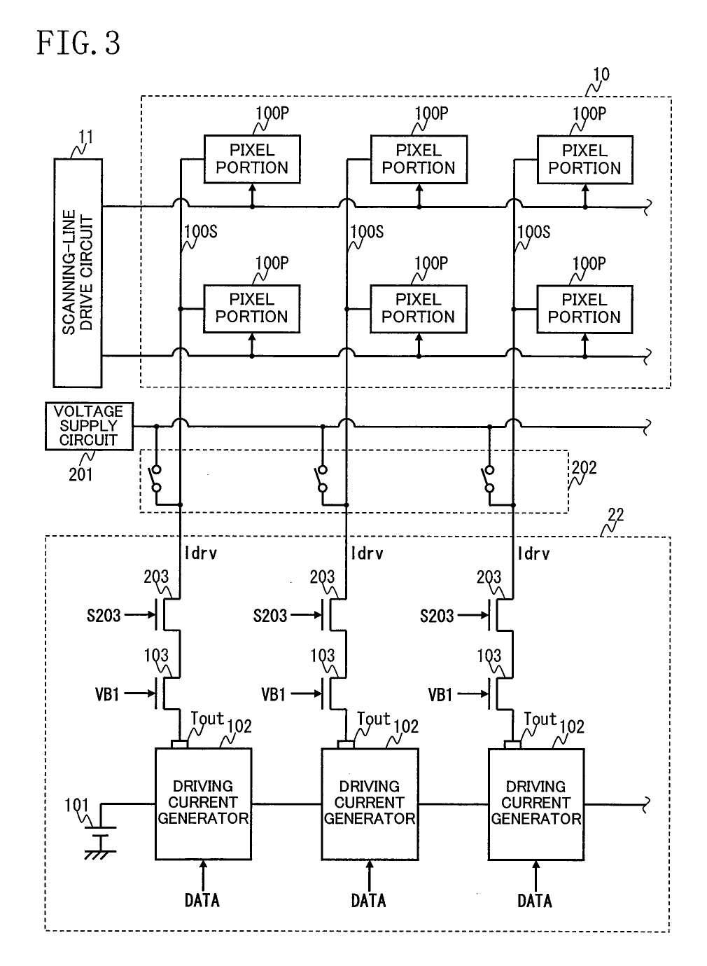

FIG. 3 illustrates a configuration of display apparatus according to a second embodiment of the present invention. The display apparatus includes: a voltage supply circuit 201; and a switch circuit 202, in addition to the components shown in FIG. 1. In this display apparatus, the current drive circuit 12 shown in FIG. 1 is replaced by a current drive circuit 22. The other part of the configuration is the same as that illustrated in FIG. 1.

### [Current Supply Circuit and Switch Circuit]

The voltage supply circuit 201 supplies an initialization voltage for initializing voltages at source lines 100S, 100S, . . . . The switch circuit 202 switches the connection state of the voltage supply circuit 201 to the source lines 100S, 100S, . . . .

During supply of a driving current Idrv to a pixel portion 100P, the driving current Idrv is used for charging/discharging a load capacitance (such as a parasitic capacitance of a line on which the driving current flows) of a driving current generator 102 so that it takes time to complete copying of the driving current Idrv in the pixel portion 100P. In the case where pixel portions 100P, 100P, . . . are driven for every horizontal line, the voltage level of a source line 100S corresponds to a driving current Idrv supplied one line earlier. Accordingly, if supply of a driving current Idrv starts without initialization of a source line 100S, the discharge amount of the source line 100S might be insufficient. If the discharge amount of the source line 100S is insufficient in this way, copying of the driving current Idrv is not completed within a given time.

The switch circuit 202 connects the source lines 100S, 100S, . . . to the voltage supply circuit 201 before copying of a driving current Idrv starts. Then, voltages of the source lines 100S, 100S, . . . are initialized. In this manner, the voltage level of a source line 100S is set at a predetermined initial value so that discharge of the source line 100S is completed within a given time, thereby accurately copying a driving current Idrv in a pixel portion 100P.

### [Current Drive Circuit]

A current drive circuit 22 of this embodiment includes control transistors 203, 203, . . . in addition to the components shown in FIG. 1. Each control transistor 203 has: a drain connected to an associated source line 100S: a source connected to the drain of an associated protective transistor 103; and a gate to which a control signal S203 for controlling ON/OFF of the control transistor 203 is supplied. The voltage level of the control signal S203 varies in a range between a conducting level (which is herein a high level) at which the control transistor 203 comes to be in a saturation region and a non-conducting level (which is herein a low level) at which the control transistor 203 comes to be in a Hi-Z state (a high-impedance state). The high level of the control signal S203 is lower than or equal to a voltage level obtained by adding the threshold voltage of the control transistor 203 to the breakdown voltage of the protective transistor 103. The low level of the control signal S203 is a ground level (i.e., 0 [V]), for example.

To initialize the voltage of the source line 100S, the control signal S203 is set at the low level. Then, the control transistor 203 turns to the Hi-Z state (i.e., a non-conducting state) so that an output terminal Tout of the driving current generator 102 is disconnected from the source line 100S. Accordingly, it is possible to perform voltage control (such as initialization of the voltage at the source line 100S) on a display panel 10 without causing breakdown of the driving current generator 102.

On the other hand, to copy a driving current Idrv in a pixel portion loop, the control signal S203 is set at the high level. Then, the control transistor 203 comes to be in a saturation region (i.e., becomes conducting) so that the output terminal Tout of the driving current generator 102 is connected to the source line 100S and, thereby, a driving current Idrv supplied from the driving current generator 102 is copied in the pixel portion loop.

In this manner, the connection state between the display panel 10 and the driving current generator 102 is switched so that the driving current generator 102 is protected against a voltage variation on the display panel 10 caused by voltage control.

### Modified Example 1 of Embodiment 2

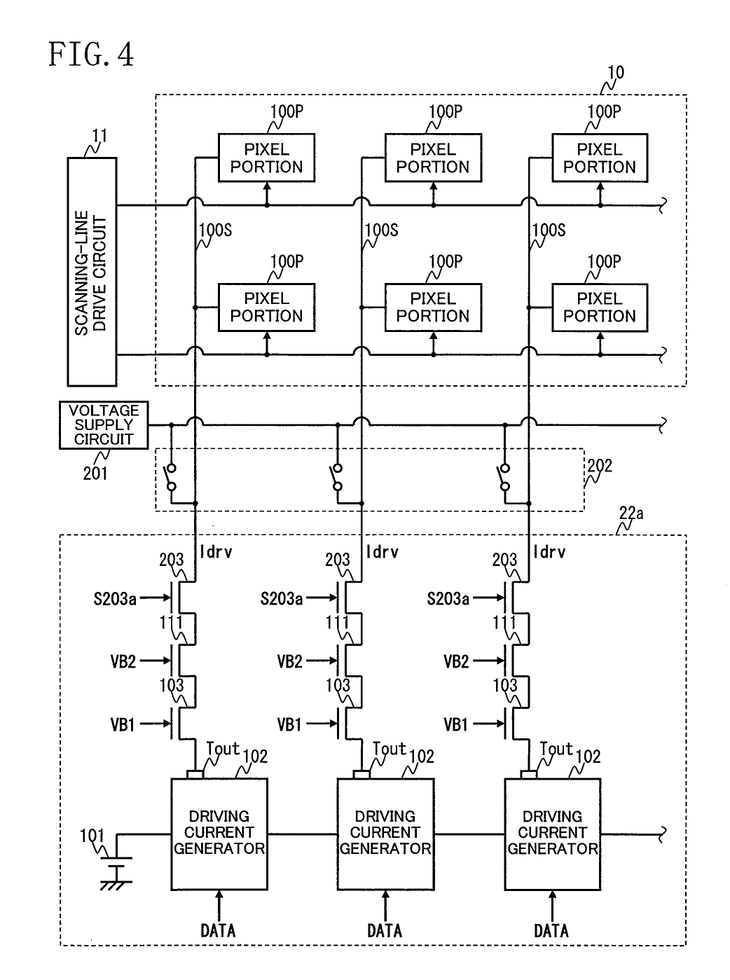

As illustrated in FIG. 4, clamping transistors 111, 111, . . . as shown in FIG. 2 may be interposed between the sources of the control transistors 203, 203, . . . and the drains of the protective transistors 103, 103, . . . . In a current drive circuit 22a shown in FIG. 4, the high level (i.e., the conducting level) of a control signal S203a supplied to the control transistor 203 is lower than or equal to a voltage level obtained by adding the threshold voltage of the control transistor 203 to the breakdown voltage of the clamping transistor 111. This configuration stabilizes the drain voltage of the protective transistor 103.

### Modified Example 2 of Embodiment 2

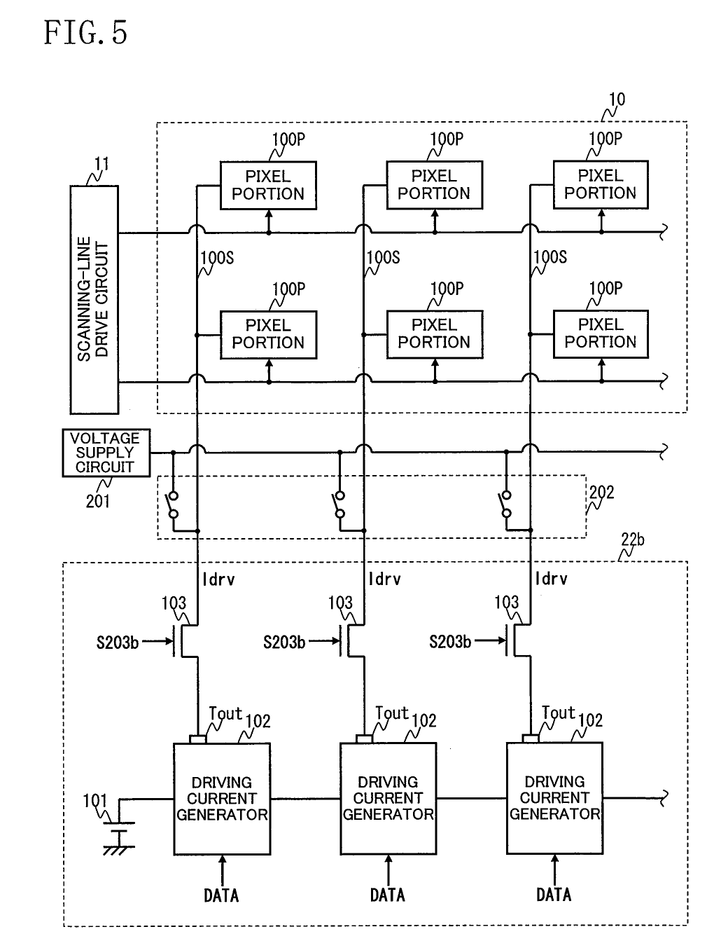

As illustrated in FIG. 5, the protective transistor 103 may be switched between ON and OFF without the control transistor 203. In a current drive circuit 22b shown in FIG. 5, the gate of the protective transistor 103 receives a control signal S203b for controlling ON/OFF of the protective transistor 103. The high level (i.e., the conducting level) of the control signal S203b corresponds to a voltage level at which the protective transistor 103 comes to be in a saturation region, and is lower than or equal to a voltage level obtained by adding the threshold voltage of the protective transistor 103 to the breakdown voltage of the driving current generator 102 (i.e., corresponds to the voltage level of the bias voltage VB1). The low level (i.e., the non-conducting level) of the control signal S203b corresponds to a voltage level at which the protective transistor 103 turns to a Hi-Z state, and is a ground level, for example. This configuration reduces the circuit scale, as compared to the current drive circuit 22 shown in FIG. 3.

### Embodiment 3

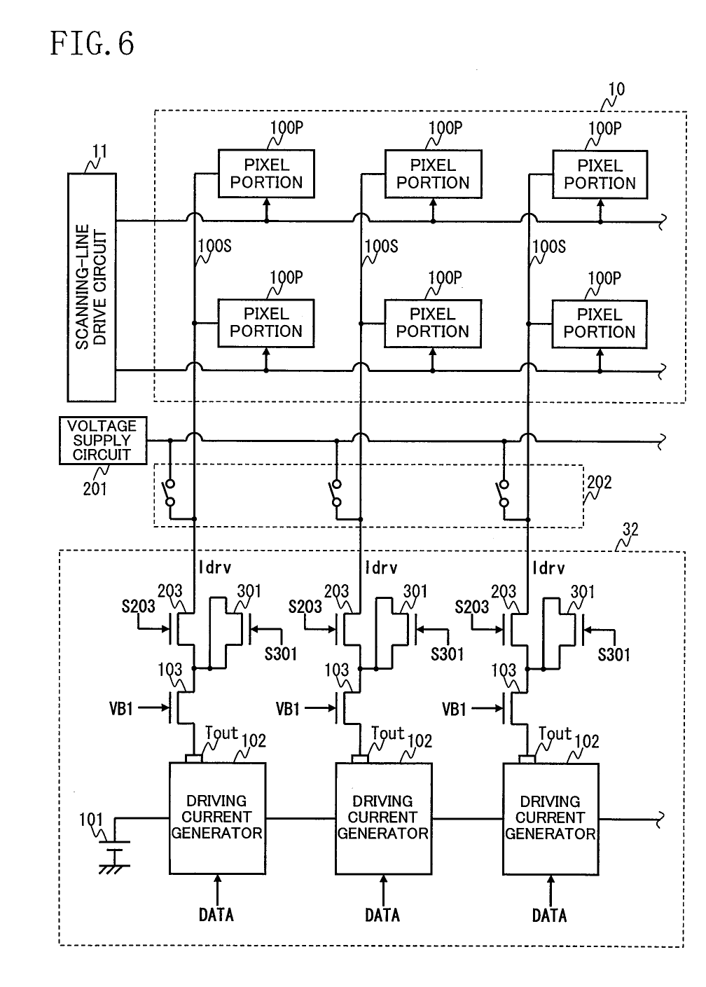

FIG. 6 illustrates a configuration of display apparatus according to a third embodiment of the present invention. In the display apparatus, the current drive circuit 22 shown in FIG. 3 is replaced by a current drive circuit 32. The current drive circuit 32 includes compensation transistors 301, in addition to the components shown in FIG. 3. The other part of the configuration is the same as that shown in FIG. 3.

Each compensation transistor 301 has: a source and a drain which are connected to the source of an associated control transistor 203; and a gate to which a compensation signal S301 for controlling ON/OFF of the compensation transistor 301 is supplied. The voltage level of the compensation signal S301 varies inversely with a variation of a control signal S203. Specifically, when the control signal S203 changes from low to high, the compensation signal S301 changes from high to low.

Each of the control transistor 203 and the compensation transistor 301 has a parasitic capacitance between its source and gate so that the source voltage of each of the control transistor 203 and the compensation transistor 301 varies according to variations of the control signals S203 and S301 (i.e., coupling noise occurs). In addition, since the voltage level of the compensation signal S301 varies inversely with a variation of the control signal S203, the source voltages of the control transistor 203 and the compensation transistor 301 also vary inversely with each other. Specifically, the source voltage of the control transistor 203 increases in the positive direction, whereas the source voltage of the compensation transistor 301 increases in the negative direction. Therefore, the variation in the source voltage of the control transistor 203 is canceled (or suppressed) by the variation in the source voltage of the compensation transistor 301.

In this manner, the variation in the source voltage of the control transistor 203 is suppressed, resulting in stabilizing the drain voltage of an associated protective transistor 103.

The compensation transistor 301 preferably has a transistor size (W/L) substantially equal to that of the control transistor 203. The high level (i.e., the conducting level) and the low level (i.e., the non-conducting level) of the compensation signal S301 are preferably substantially equal to those of the control signal S203. Then, the variation range in the source voltage of the control transistor 203 is further reduced, thus enhancing stability of the drain voltages of the protective transistor 103.

### Modified Example 1 of Embodiment 3

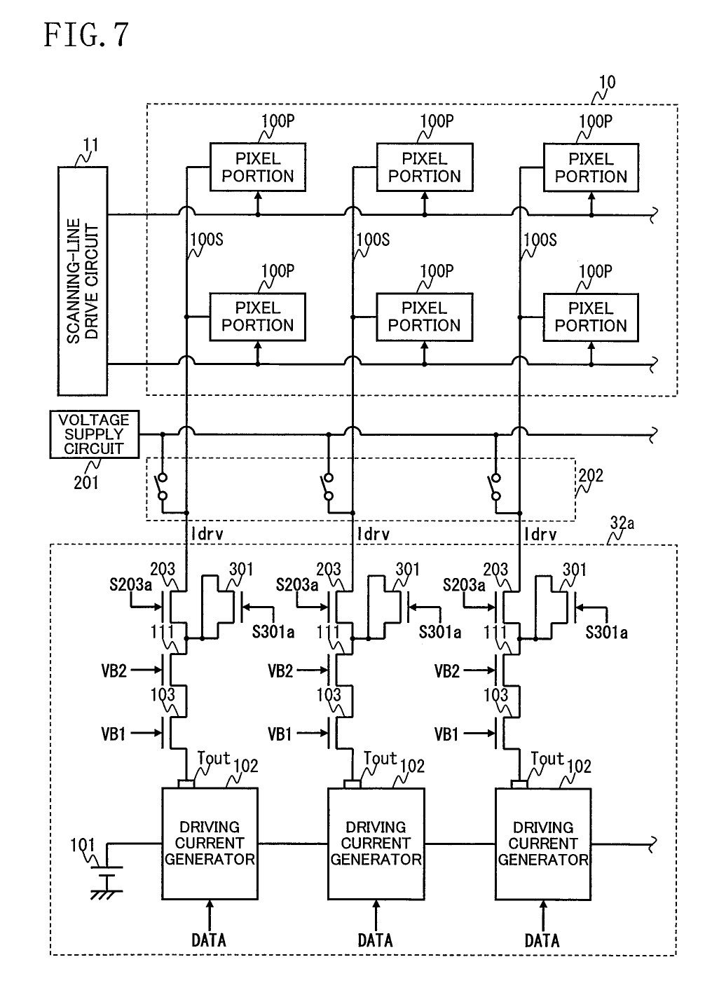

As illustrated in FIG. 7, clamping transistors 111, 111, . . . as shown in FIG. 2 may be interposed between the sources of the control transistors 203 and the drains of the protective transistors 103. In a current drive circuit 32a shown in FIG. 7, the voltage level of a compensation signal S301a varies inversely with a variation of a control signal S203a. This configuration stabilizes the drain voltages of the clamping transistors 111, resulting in further stabilizing the drain voltages of the protective transistors 103.

The high and low levels of the compensation signal S301a supplied to the compensation transistor 301 are preferably substantially equal to those of the control signal S203a supplied to the control transistor 203.

### Modified Example 2 of Embodiment 3

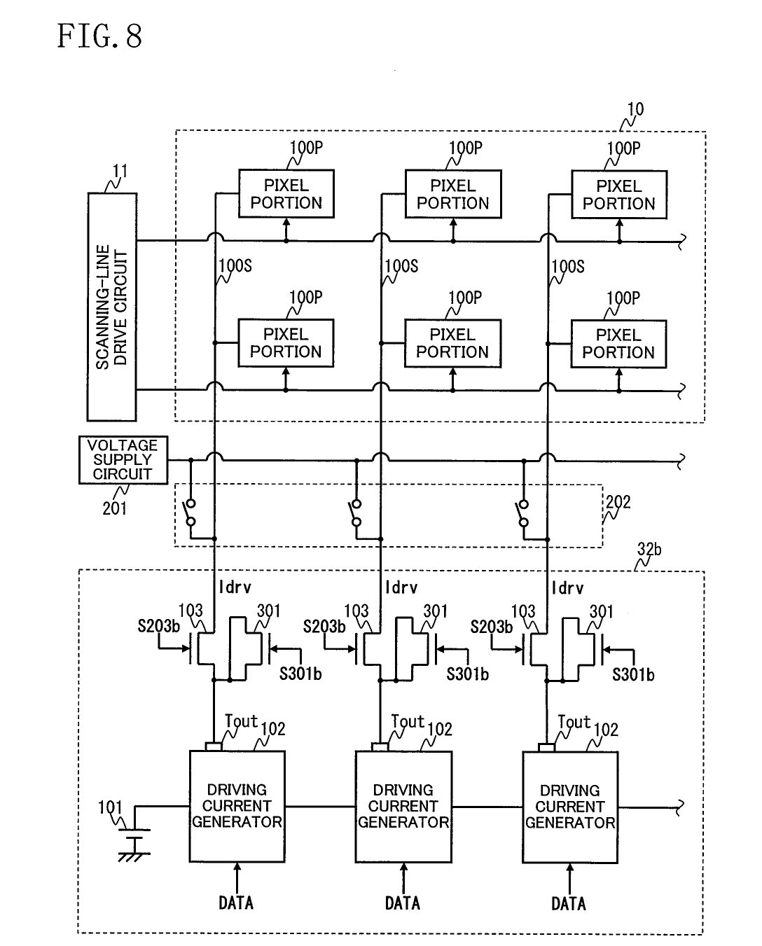

As illustrated in FIG. 8, the protective transistor 103 may be switched between ON and OFF without the control transistor 203. In a current drive circuit 32b shown in FIG. 8, the voltage level of a compensation signal S301b varies inversely with a variation of a control signal S203b.

The transistor size of the compensation transistor 301 is preferably substantially equal to that of the protective transistor 103. The high and low levels of the compensation signal S301b supplied to the compensation transistor 301 are preferably substantially equal to those of the control signal S203b supplied to the protective transistor 103.

### Embodiment 4

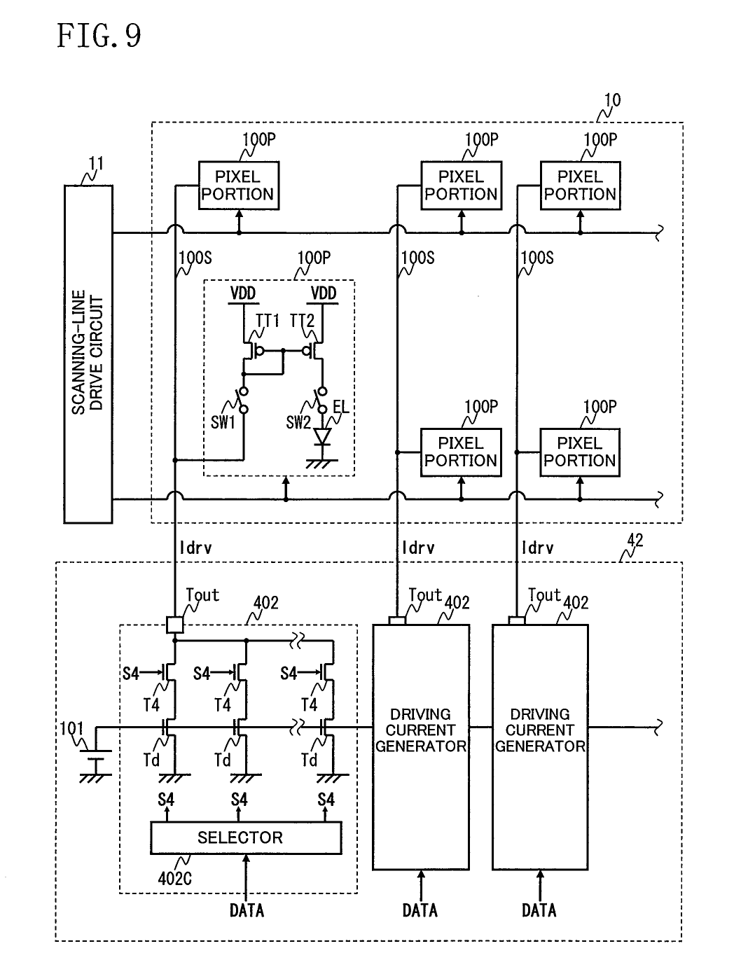

FIG. 9 illustrates a configuration of display apparatus according to a fourth embodiment of the present invention. In the display apparatus, the current drive circuit 12 shown in FIG. 1 is replaced by a current drive circuit 42. The current drive circuit 42 includes: a voltage source 101 as shown in FIG. 1; and driving current generators 402, 402, . . . Each driving current generator 402 includes: switching transistors T4, T4, . . . ; and a selector 402C, instead of the switches SWd, SWd . . . and the selector 102C shown in FIG. 1. The other part of the configuration is the same as that shown in FIG. 1.

Each switching transistor T4 has: a drain connected to an output terminal Tout; a source connected to the drain of an associated drive transistor Td; and a gate to which a selection signal S4 for controlling ON/OFF of the switching transistor T4 is supplied. The voltage level of the control signal S4 varies in a range between a conducting level (which is herein a high level) at which the switching transistor T4 comes to be in a saturation region and a non-conducting level (which is herein a low level) at which the switching transistor T4 comes to be in a Hi-Z state. The high level of the control signal S4 is lower than or equal to a voltage level obtained by adding the threshold voltage of the switching transistor T4 to the breakdown voltage of the drive transistor Td.

The selector 402C sets the voltage levels of selection signals S4, S4, according to display data DATA. This causes one or more, or all, of the switching transistors T4, T4, . . . to turn ON. Since a high-level selection signal S4 is supplied to the gate of the ON-state switching transistor T4, the drain voltage of the drive transistor Td connected to the source of this switching transistor T4 becomes lower than or equal to the voltage level obtained by subtracting the threshold voltage of the switching transistor T4 from the high level of the selection signal S4. That is, the drain voltage of the drive transistor Td is limited below the breakdown voltage of the drive transistor Td.

Since the ON-state switching transistor T4 operates in a saturation region, no current variation occurs between the source and drain of the switching transistor T4. Accordingly, a current generated by the drive transistor Td is accurately supplied to the output terminal Tout through the ON-state switching transistor T4. This enables a driving current Idrv corresponding to display data DATA to be accurately generated.

As described above, the drain voltage of the drive transistor Td is limited by the switching transistor T4, thereby preventing breakdown of the drive transistor Td. In addition, the breakdown voltage of the drive transistor Td is allowed to be set independently of the power supply voltage of a display panel 10 so that the breakdown voltage of the drive transistor Td is lower than that in conventional circuits. This reduces the circuit scale and fabrication cost of the current drive circuit 42.

Moreover, the voltage level of a voltage applied to the drain of the drive transistor Td in writing a driving current Idrv is allowed to be set lower than that in conventional circuits. Thus, the life of the drive transistor Td is longer than that in conventional circuits. In this manner, characteristic deterioration caused by using the drive transistor Td is suppressed, thus accurately supplying a driving current Idrv for a longer period than in conventional circuits.

### Other Embodiments

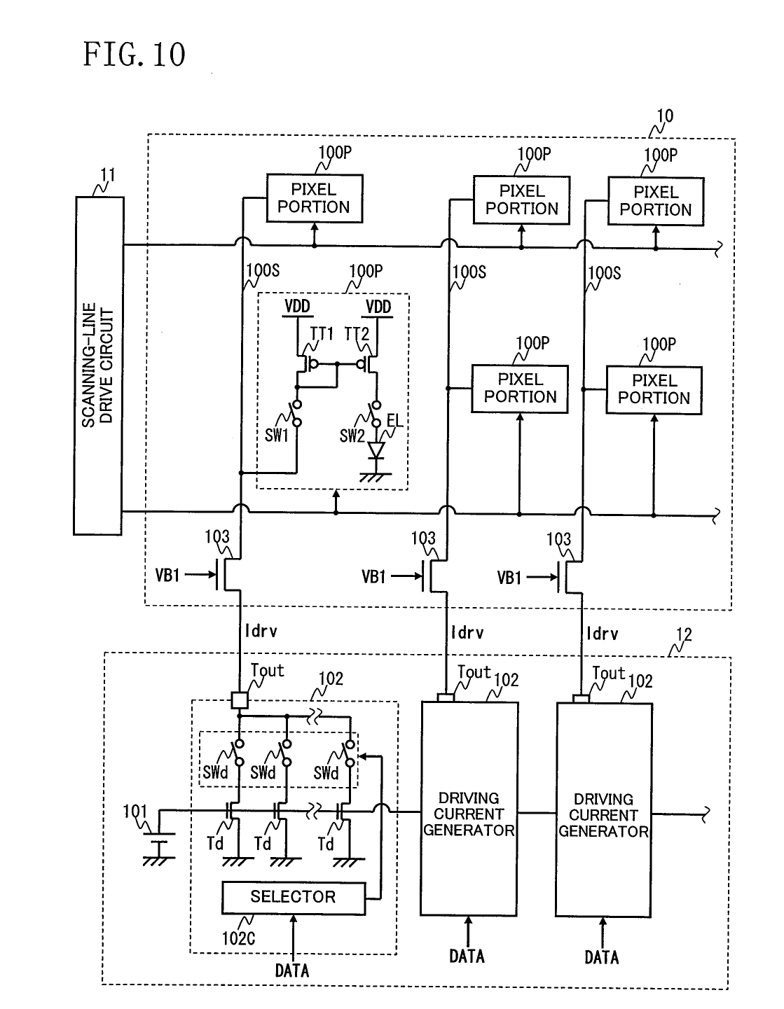

As illustrated in FIG. 10, protective transistors 103 are not necessarily incorporated in a current drive circuit 12 and may be incorporated in a display panel 10. The same holds for clamping transistors 111, control transistors 203 and compensation transistors 301.

The display panel 10 and the current drive circuit 12 may be united as display apparatus. Specifically, the current drive circuit 12 may be embedded in a frame of the display panel 10 (i.e., the periphery of a display screen). This structure eliminates the need for connection pads for connecting circuits, thus reducing the package area. In addition, the wire lengths among circuits are also reduced.

In the foregoing description, organic EL devices are used as an example of current-driven light-emitting devices. Alternatively, inorganic EL devices or field emission displays (FEDs) may be used.

Although the current drive circuits of a current pull-in type are exemplified in the embodiments, the foregoing description is also applicable to current drive circuits of a current ejection type.

The current drive circuits according to the present invention are useful for current-driven display panels (such as organic EL panels, inorganic EL panels and FED panels).

What is claimed is:

1. A current drive circuit for supplying a driving current to a pixel portion included in a current-driven display panel, the current drive circuit comprising:
a driving current generator including an output terminal for supplying the driving current; and
a protective transistor having a drain connected to the pixel portion, a source connected to the output terminal, and a gate to which a first bias voltage is supplied,
wherein the first bias voltage has a voltage level lower than or equal to a voltage level obtained by adding a threshold voltage of the protective transistor to a breakdown voltage of the driving current generator.

2. The current drive circuit of claim 1, further comprising a control transistor interposed between the pixel portion and the protective transistor,
wherein the control transistor has a drain connected to the pixel portion, a source connected to the drain of the protective transistor, and a gate to which a control signal for controlling ON/OFF of the control transistor is supplied.

3. The current drive circuit of claim 2, further comprising a compensation transistor having a drain, a source and a gate, the drain and the source of the compensation transistor being connected to the source of the control transistor, the gate of the compensation transistor receiving a compensation signal,
wherein the compensation signal is a signal for controlling ON/OFF of the compensation transistor, and
a voltage level of the compensation signal varies inversely with a variation of the control signal.

4. The current drive circuit of claim 1, wherein the first bias voltage is supplied concurrently with, or before, start-up of the driving current generator.

5. The current drive circuit of claim 1, further comprising a clamping transistor interposed between the pixel portion and the protective transistor,
wherein the clamping transistor has a drain connected to the pixel portion, a source connected to the drain of the protective transistor, and a gate to which a second bias voltage having a voltage level lower than or equal to a voltage level obtained by adding a threshold voltage of the clamping transistor to a breakdown voltage of the protective transistor is supplied.

6. The current drive circuit of claim 5, further comprising a control transistor interposed between the pixel portion and the clamping transistor,
wherein the control transistor has a drain connected to the pixel portion, a source connected to the drain of the clamping transistor, and a gate to which a control signal for controlling ON/OFF of the control transistor is supplied.

7. The current drive circuit of claim 6, further comprising a compensation transistor having a drain, a source and a gate, the drain and the source of the compensation transistor being connected to the source of the control transistor, the gate of the compensation transistor receiving a compensation signal,
wherein the compensation signal is a signal for controlling ON/OFF of the compensation transistor, and
a voltage level of the compensation signal varies inversely with a variation of the control signal.

8. The current drive circuit of claim 1, wherein a control signal for controlling ON/OFF of the protective transistor is supplied to the gate of the protective transistor, and
a voltage level of the control signal varies in a range between a non-conducting level at which the protective transistor is OFF and a conducting level lower than or equal to a voltage level obtained by adding a threshold voltage of the protective transistor to a breakdown level of the driving current generator.

9. The current drive circuit of claim 8, further comprising a compensation transistor having a drain, a source and a gate, the drain and the source of the compensation transistor being connected to the source of the protective transistor, the gate of the compensation transistor receiving a compensation signal,
wherein the compensation signal is a signal for controlling ON/OFF of the compensation transistor, and
a voltage level of the compensation signal varies inversely with a variation of the control signal.

10. A display apparatus, comprising:
the current drive circuit recited in claim 1; and
the display panel recited in claim 1.

11. A current drive circuit for supplying a driving current to a pixel portion included in a current-driven display panel, the current drive circuit comprising:
a plurality of drive transistors; and
a plurality of switching transistors each connected between an associated one of the drive transistors and an output terminal for supplying the driving current,
wherein each of the switching transistors has a drain connected to the output terminal, a source connected to a drain of an associated one of the drive transistors, and a gate to which a selection signal for controlling ON/OFF of the switching transistor is supplied, and
a voltage level of the selection signal varies in a range between a non-conducting level at which the switching transistor is OFF and a conducting level lower than or equal to a voltage level obtained by adding a threshold voltage of the switching transistor to a breakdown level of the drive transistor.

12. A display apparatus, comprising:
the current drive circuit recited in claim 11; and
the display panel recited in claim 11.

13. A current-driven display panel driven by a driving current supplied from an output terminal of a current drive circuit, the display panel comprising:
a pixel portion to which the driving current is supplied; and
a protective transistor having a drain connected to the pixel portion, a source connected to the output terminal, and a gate to which a bias voltage is supplied,
wherein the bias voltage has a voltage level lower than or equal to a voltage level obtained by adding a threshold voltage of the protective transistor to a breakdown voltage of the current drive circuit.
